(19) United States
(12) Patent Application Publication
(10) Pub. No.: US 2025/0028234 A1
(43) Pub. Date: Jan. 23, 2025

(54) PELLICLE FOR EXTREME ULTRAVIOLET LITHOGRAPHY AND METHOD FOR MANUFACTURING SAME

(71) Applicant: INFOVION INC., Bucheon-si, Gyeonggi-do (KR)

(72) Inventor: Yong Hwan KIM, Gyeonggi-do (KR)

(73) Assignee: INFOVION INC., Bucheon-si, Gyeonggi-do (KR)

(21) Appl. No.: 18/715,438

(22) PCT Filed: Nov. 25, 2022
(86) PCT No.: PCT/KR2022/018831

§ 371 Date: May 31, 2024

(30) Foreign Application Priority Data
Dec. 1, 2021 (KR) 10-2021-0170077
Nov. 23, 2022 (KR) 10-2022-0158094

(51) Int. Cl. G03F 1/22

(52) U.S. Cl. CPC G03F 1/22

(57) ABSTRACT

Disclosed are: a pellicle for EUV lithography, which simultaneously satisfies the high transmittance and mechanical strength of crystalline silicon and can be manufactured in a large area, and a method for manufacturing the same.

### CROSS-REFERENCE TO RELATED APPLICATION(S)

This application is based on and claims benefits of priority based on Korean Patent Application Nos. 10-2021-0170077 and 10-2022-0158094, filed on Dec. 1, 2021 and Nov. 23, 2022, respectively, and all contents disclosed in documents of the corresponding Korean Patent Applications are herein incorporated as parts of this specification.

### TECHNICAL FIELD

The present disclosure relates to a pellicle for extreme ultraviolet (EUV) lithography and a method for manufacturing the same.

### BACKGROUND ART

In a semiconductor pattern forming process, improvement of lithography technology for reducing the line width of a semiconductor is necessary to improve integrity.

Recently, as large semiconductor companies and IT electronic device companies launch products each having the semiconductor line width that is equal to or smaller than 10 nm, the lithography process has been changed from the previous ArF method to the extreme ultraviolet (EUV) irradiation method. In the feature size that is equal to or smaller than 10 nm, it is difficult to form a clear pattern in the existing ArF method, whereas in the latest lithography process using an EUV light source having a wavelength of 13.5 nm, it is possible to apply the feature size that is equal to or smaller than 10 nm.

In the lithography process, although the existing ArF method adopts a method in which a light source penetrates an existing pattern mask, the EUV lithography has been changed to the reflecting method, and the process has also been progressed in a high vacuum atmosphere.

In the EUV lithography, an EUV reticle (pattern mask or photo mask) is used, and the reticle is formed as a mask pattern on a high-purity quartz substrate.

The mask pattern is composed of a reflective layer and an absorption layer, and the absorption layer is finally stacked on the reflective layer obtained by stacking, in a row, 80 layers of Mo (3 nm) layers and Si (4 nm) layers composed of low refractive layers and high refractive layers, respectively, through capping/buffer layers.

By etching, in accordance with the shape of the line with of the semiconductor pattern, the buffer/capping layers including the buffer layer stacked on the capping layer that protects the Mo/Si reflective layers, the EUV mask (reticle) is completed.

If the EUV light arrives at the mask, EUV absorption occurs on the absorption layer of a remaining region excluding the etched pattern, and if the EUV is reflected by the reflective layer that is exposed through etching in accordance with the pattern shape, the light reflected in the pattern shape arrives at the substrate to form an image thereon.

In this method, if a pollution factor or dust flows in on the mask pattern, that is, reticle, a pattern failure may occur. In particular, as the feature size becomes smaller, the need to block such a pollution factor or dust is increased. Accordingly, the reticle should be protected against the pollution factor or dust by mounting a film-shaped pellicle filter on a front part of the reticle.

At present, although developments of the EUV process have mostly been completed, a pellicle that satisfies transmittance suitable for mass production has not been developed, and in order to enter the mass production of an ultrahigh integration (3 nm or less) semiconductor in the future in addition to an amount equivalent to tens of millions of won per sheet, such a pellicle should be developed.

The requirements for the pellicle to be applied are to require a high numerical value of transmittance for an EUV light source so as to be at least 90% or more, to secure a sufficient mechanical strength enough to endure a pressure difference occurring when vacuum is exhausted, to endure a high temperature to be arisen by irradiation of the EUV light source, and to have a chemical stability for not being etched by hydrogen in a situation that a large amount of hydrogen is administered.

At present, although a Si material has the highest EUV transmittance and achieves 86% thereof as the results of developments in respective research groups including domestic groups, it is required to lower the thickness thereof to 50 nm or less for transmittance improvement, and thus there is a problem in that the mechanical properties are degraded.

Although candidate materials, such as SiC, SiN, and CNT, have been used to supplement this, most of them do not satisfy the transmittance or a required area (110×144 mm²).

KR Patent Application Publication No. 10-2015-0123145 discloses a pellicle which includes a single-layer graphene, a double-layer graphene or a multilayer graphene material, having a high mechanical strength, and thus can quickly dissipate a high-temperature heat being generated from the EUV during the lithography process.

However, since such a film has a weak strength, various support films or reinforced films for reinforcement have been used, and multilayer thin films having various structures, such as mesh or porous films, have been used.

Further, since the graphene composed of carbon atoms has the characteristics of being etched in an atmosphere with a large amount of hydrogen, an additional protection film is required on the graphene.

As materials of the support film or reinforced film, materials, such as Si, Ru, Ir, Au, Rh, and C, or inorganic films, such as AIN, SiN, and SiC, have been used. Through the use of such materials, there is an advantage in that the durability of the pellicle film is improved, but its manufacturing process is complicated, and in case of some materials, there remains a problem of the EUV transmittance.

(Patent Document 1) KR Patent Application Publication No. 10-2015-0123145 (Published on Nov. 3, 2015)

(Patent Document 2) KR Patent Application Publication No. 10-2018-0109498 (Published on Oct. 8, 2018)

### DISCLOSURE

### Technical Problem

The inventor has conducted multifaceted researches for enabling a pellicle film to have a large area while simplifying process conditions when the pellicle film in which a graphene layer and a crystallized silicon (c-Si) layer are heterojunctioned is manufactured so as to heighten an EUV transmittance while maintaining excellent mechanical properties of the graphene. As a result, a new method capable of making a stacked structure of c-Si/graphene or c-Si/SiC/graphene has been developed through forming of the graphene layer, silicon crystalline, and diffusion of a Si-C interface through electron beam irradiation after forming a precursor layer for manufacturing the respective layers.

Accordingly, an object of the present disclosure is to provide a pellicle for EUV lithography and a method for manufacturing the same.

### Technical Solution

In order to achieve the above object, the present disclosure provides a pellicle for extreme ultraviolet (EUV) lithography including a pellicle film that is penetrated by extreme ultraviolet rays and a support frame that supports the pellicle film.

The pellicle film has a multilayer thin film structure in which a c-Si layer and a graphene thin film are heterojunctioned.

The c-Si is crystallized silicon having no μm-sized grain boundary, and is obtained by crystalizing a deposited amorphous silicon thin film through heating by electron beam irradiation, and the graphene thin film is also obtained by crystalizing a graphene precursor or a carbon thin film into a graphene thin film through the electron beam irradiation.

The Si crystallized by the electron beam irradiation shows crystallization peaks on surfaces of (111), (220), and (311) in an X-ray diffraction (XRD) analysis spectrum, and has a Raman shift at 520 cm⁻¹ that represents Si crystallized by the electron beam irradiation in a Raman analysis, unlike 480 cm⁻¹ that represents an amorphous silicon.

Crystallization of amorphous silicon by laser irradiation has a grain boundary of a several μm size, but c-Si crystallized by the electron beam irradiation does not show the grain boundary of the μm size. If a crack that starts on one side of a pellicle occurs when an external force or impact occurs, and in particular, there is a difference in vacuum pressure between front and back surfaces of the pellicle, the pellicle destruction occurs through propagation of the crack along the grain boundary, and thus the crystallized silicon c-Si having no grain boundary can be used as a material of excellent properties which can increase the strength of the pellicle and increase the transmittance of the EUV.

In this case, as the pellicle film, any one of c-Si/graphene, graphene/c-Si, c-Si/SiC/graphene, graphene/SiC/c-Si, c-Si/graphene/c-Si, graphene/c-Si/graphene, c-Si/SiC/graphene/SiC/c-Si, and graphene/SiC/c-Si/SiC/graphene structures may be used, or a part of various pellicle film stacked structure arrays may be used.

The thickness of the pellicle film may be 5 to 50 nm.

Further, the present disclosure provides a method for manufacturing a pellicle for extreme ultraviolet (EUV) lithography including a pellicle film that is penetrated by ultraviolet rays and a support frame that supports the pellicle film.

Specifically, the method includes the steps of:

(S1) forming a multilayer including a carbon layer, a metal catalyst layer, and an amorphous silicon layer on a substrate:

(S2) finally forming a multilayer thin film in which the c-Si layer and a graphene layer are heterojunctioned by simultaneously or sequentially performing steps of crystallizing the amorphous silicon layer with changing the amorphous silicon layer to a c-Si layer while a surface of the amorphous silicon layer is heated through irradiation of an electron beam thereto and the heat is diffused downward, diffusing carbon of the carbon layer by making the carbon of the carbon layer come up to an interface of the c-Si/metal catalyst layers through the metal catalyst layer, and then making the come-up carbon form a graphene at the interface:

(S3) performing diffusion bonding through a binder layer by making a support frame come in face-to-face contact with the binder layer on an outer periphery of the multiplayer after forming the binder layer on the outer periphery of the multilayer and forming the binder layer also on a surface of the face-to-face support frame; and

(S4) lifting off the multilayer thin film attached to the frame from the substrate.

In this case, in case that the metal catalyst layer remains on an uppermost layer of the multilayer thin film, the multilayer thin film of the c-Si/graphene is left on the frame through etching of the metal catalyst layer.

In addition, after the step (S4), the method further includes the steps of:

(S5) forming any one or more of the amorphous silicon layer and the carbon layer on a bottom surface on an opposite side of the frame of the multilayer thin film attached to the frame; and

(S6) forming any one or more of the c-Si layer and the graphene layer on the bottom surface by irradiating the bottom surface with the electron beam.

Through the above-described steps, according to the present disclosure, the pellicle film having an asymmetric structure of c-Si/graphene, graphene/c-Si, c-Si/SiC/graphene, and graphene/SiC/c-Si, being bonded to the frame is competed.

Through the additional steps, the pellicle film having a symmetric structure of c-Si/graphene/c-Si, graphene/c-Si/graphene, c-Si/SiC/graphene/SiC/c-Si, and graphene/SiC/c-Si/SiC/graphene, being bonded to the frame is completed.

In the present disclosure, the multilayer film before processing of the electron beam may be one multilayer film selected from the group consisting of an amorphous silicon layer/metal catalyst layer/carbon layer/substrate, an amorphous silicon layer/carbon layer/metal catalyst layer/substrate, a carbon layer/metal catalyst layer/amorphous silicon layer/substrate, a carbon layer/amorphous silicon layer/metal catalyst layer/substrate, a metal catalyst layer/carbon layer/amorphous silicon layer/substrate, and a metal catalyst layer/amorphous silicon layer/carbon layer/substrate.

The metal catalyst layer may be a single metal selected from the group consisting of Ni, Ti, Al, Zn, Co, Cu, Pt, Ag, and Au having an FCC structure or an alloy of two or more of the metals.

The carbon layer is formed through graphene curing coating, or sputtering or vacuum deposition by coating and then curing a graphene precursor solution.

The diffusion bonding is performed by applying a pressure of 0.1 Mpa to 1.0 Mpa at a temperature of 300° C. to 600° C.

A binder layer for the diffusion bonding is any one of a low-temperature melting metal; an eutectic alloy of which the melting temperature is lowered while Zn, Ga, In, Sn, Au and Al, Si, Ti, Cr, Mn, Fe, Co, Ni, Cu, Zr, Nb, Mo, Te, Ru, Pd, Ag, and Pt are alloyed together; and a general alloy, and includes one selected from the group consisting of their oxide, nitride, carbide, and boride.

The substrate is preprocessed through any one or more of plasma implantation processing onto an Si wafer, hydrophobic plasma processing, or separation layer deposition, or is preprocessed through hydrophobic plasma processing on various kinds of metals or ceramics or a quartz plate or separation layer deposition.

The lift-off is performed by separating the substrate and the multilayer thin film from each other through eruption of hydrogen and helium from an interface with the substrate or a separation layer compound and eruption of nitride and oxygen decomposed from the separation layer compound through heat treatment, RTA heat treatment, and electron beam or laser irradiation on a rear surface of the substrate after the plasma implantation and the separation layer deposition.

The lift-off may also be performed by leaving the remaining multilayer film by etching the substrate or by etching and removing a middle film between the substrate and the multilayer film.

In the above-described implementation examples, a SiC layer may be formed on a Si/carbon interface through reaction of the Si and the carbon, and the formation and the thickness of the SiC layer can be controlled by adjusting an energy irradiation time of the electron beam.

In the above-described implementation examples, the amorphous silicon may be crystallized simultaneously with crystallization of the graphene after the multilayer thin film is formed, and as needed, crystallization of the silicon only may be immediately performed after the silicon deposition.

In the above-described implementation examples, the metal catalyst layer may act as a catalyst not only in crystalizing the amorphous silicon but also in crystalizing the carbon layer to the graphene, and the metal catalyst layer may be finally removed by an etchant.

In the above-described implementation examples, for the lift-off of the pellicle from the substrate, a step of preprocessing the substrate may be put before the multilayer thin film is deposited on the substrate, or a step of depositing separation layer thin films that are required for the lift-off may be put.

In the above-described implementation examples, by making the multilayer thin film in a mirror structure through combination of the multilayer thin film deposition, the electron beam irradiation, and the etching order of the metal catalyst layer disposed outermost, and by adjusting forming of an SiC layer on an Si/C interface through additional adjustment of an electron beam irradiation time, it is possible to form various multilayer thin films including SiC of c-Si/SiC/graphene, graphene/SiC/c-Si, c-Si/SiC/graphene/SiC/c-Si, and graphene/SiC/c-Si/SiC/graphene.

In the above-described implementation examples, the heating method by the electron beam irradiation may be possible even by general heat treatment, RTA heat treatment, and laser irradiation.

Further, the present disclosure provides the pellicle that is used to protect the reticle from dust.

For the electron beam, one or a plurality of electron beam sources may be used, the electronic beam sources may be disposed in series or in parallel, and a circular or linear beam may be used. For the electron beam irradiation, one or a plurality of electron beam sources may be used, the electronic beam sources may be disposed in series or in parallel, and a circular or linear beam may be used.

The electron beam may be irradiated through transporting of a support at a predetermine speed in a state where an electron beam source is fixed, or may be irradiated through transporting of an electron beam source in a state where a support is fixed. The electron beam may be irradiated on the substrate with a voltage of 50 eV to 50 keV. The electron beam irradiation may be performed under the existence of an inert gas, and the inert gas may be selected from nitrogen, helium, neon, argon, xenon, or a mixture of one or more of them.

The carbon layer may be a graphene precursor, and as the graphene precursor, polyimide, polyacrylonitrile, polymethyl methacrylate, polystyrene, rayon, lignin, pitch, borazine oligomer, or a mixture of one or more of them may be used. Here, as a solvent that is used to dissolve the graphene precursor, at least one of dimethylformamide (DMF), formaldehyde, chloroform, dimethylacetamide (DMA), pyridine, benzopyridine, benzene, xylene, toluene, dioxane, tetrahydrofuran (THF), diethyl ether, dimethyl sulfoxide (DMSO), and n-methyl-2-pyrrolidone (NMP) may be selected and used.

The carbon layer can be formed through any one method of graphene curing coating or chemical vapor deposition (CVD), plasma enhanced chemical vapor deposition (PECVD), sputtering, graphite ion beam deposition (IBD), physical vapor deposition, and vacuum deposition after coating and then curing of a graphene precursor solution. Further, in the sputtering, graphite ion beam deposition (IBD), physical vapor deposition, and vacuum deposition, the carbon source may be made through a process of singly using a graphite target or pellet or additionally adding a hydrocarbon gas thereto.

### Advantageous Effects

Since the method for manufacturing a pellicle for EUV lithography according to the present disclosure has a very simple process, and can process over a pellicle size (140 mm×114 mm) that is required for the EUV process by using a linear electron beam, it is possible to produce the pellicle having uniform properties.

Since the graphene layer and the c-Si layer in the pellicle film manufactured as above are high-quality thin films having almost no defect, it is easy to adjust the properties and the thickness during the manufacturing process.

In particular, according to the present disclosure, the crystallized silicon and the graphene thin film are simultaneously formed by the electron beam with a structure in which they form a continuous layer, and thus the crystallized silicon does not have grain boundary, and the graphene thin film can be produced on a large area. In this case, during the electron beam irradiation through forming of the metal catalyst layer in the middle, both the crystallized silicon and the graphene are simultaneously produced to form the structure in which they are bonded on the interface.

Since the pellicle according to the present disclosure can simultaneously secure high transmittance by the c-Si and mechanical strength by the graphene layer, the pellicle has high EUV transmittance and excellent durability against the EUV when being applied to the pellicle for the EUV lithography, and thus secures the strength enough to endure the pellicle manufacturing process or the atmospheric pressure to vacuum process in the EUV lithography system.

### BRIEF DESCRIPTION OF DRAWINGS

FIG. 1 is a cross-sectional view showing a pellicle according to one implementation example of the present disclosure.

FIG. 2 is a cross-sectional view showing a pellicle according to another implementation example of the present disclosure.

FIG. 3 is a cross-sectional view showing a shape in which a pellicle according to one implementation example of the present disclosure is mounted in front of a reticle.

FIG. 4 is a schematic diagram showing a beam shape of an electron beam source.

FIG. 5 is a schematic diagram showing irradiation of a linear electron beam on a large substrate according to one implementation example of the present disclosure.

FIG. 6 is a schematic diagram showing Q-Q′ cutting surface of FIG. 5.

FIG. 7 shows X-ray diffraction of amorphous silicon and crystallized silicon before and after electron beam irradiation.

FIG. 8 is a Raman graph of amorphous silicon and crystallized silicon before and after electron beam irradiation.

FIG. 9 shows a scanning electron microscope image of crystallized silicon (a) formed by electron beam irradiation and crystallized silicon (b) formed by laser irradiation.

FIG. 10 shows a Raman spectrum of a graphene layer manufactured in embodiment 1.

### BEST MODE

According to one implementation example of the present disclosure, a pellicle for extreme ultraviolet (EUV) lithography including a pellicle film that is penetrated by extreme ultraviolet (EUV) rays and a support frame that supports the pellicle film may be provided, wherein the pellicle film has a multilayer thin film structure in which a crystallized silicon (c-Si) layer having no μm-sized grain boundary and a graphene thin film are heterojunctioned.

According to another implementation example of the present disclosure, in order to manufacture a pellicle for lithography including a pellicle film that is penetrated by extreme ultraviolet (EUV) rays and a support frame that supports the pellicle film, a method for manufacturing a pellicle for EUV lithography includes the steps of:

(S1) forming a multilayer including a carbon layer, a metal catalyst layer, and an amorphous silicon layer on a substrate:

(S2) finally forming a multilayer thin film in which the c-Si layer and a graphene layer are heterojunctioned by simultaneously or sequentially performing steps of crystallizing the amorphous silicon layer with changing the amorphous silicon layer to a c-Si layer while a surface of the amorphous silicon layer is heated through irradiation of an electron beam thereto and the heat is diffused downward, diffusing carbon of the carbon layer by making the carbon of the carbon layer come up to an interface of the c-Si/metal catalyst layers through the metal catalyst layer, and then making the come-up carbon form a graphene at the interface:

(S3) performing diffusion bonding through a binder layer by making a support frame come in face-to-face contact with the binder layer on an outer periphery of the multiplayer after forming the binder layer on the outer periphery of the multilayer and forming the binder layer also on a surface of the face-to-face support frame; and

(S4) lifting off the multilayer thin film attached to the frame from the substrate.

According to still another implementation example of the present disclosure, in order to protect the photo mask from dust, a reticle for EUV lithography provided with the pellicle may be provided.

### Mode for Disclosure

Hereinafter, embodiments of the present disclosure will be described in detail with reference to the accompanying drawings so that those of ordinary skill in the art to which the present disclosure pertains can easily embody the present disclosure. However, the present disclosure can be implemented in various different forms, and is not limited to the embodiments to be described hereinafter. Further, in order to clearly describe the present disclosure in the drawings, portions that are not related to the description are omitted, and throughout the entire specification, similar reference numerals are given to similar parts. Further, for convenience in explanation, the sizes of constituent elements in the drawings may be exaggerated or reduced.

In the entire specification of the present disclosure, when a certain member is located “on”, “above”, “at the top of”, “under”, “below”, or “at the bottom of” another member, this includes not only a case where a certain member comes in contact with another member but also a case where still another member exists between the two members.

In the entire specification of the present disclosure, when a certain part “includes” a certain constituent element, this means that, unless specifically described on the contrary, another constituent element may not be excluded, but may be further included.

### Pellicle

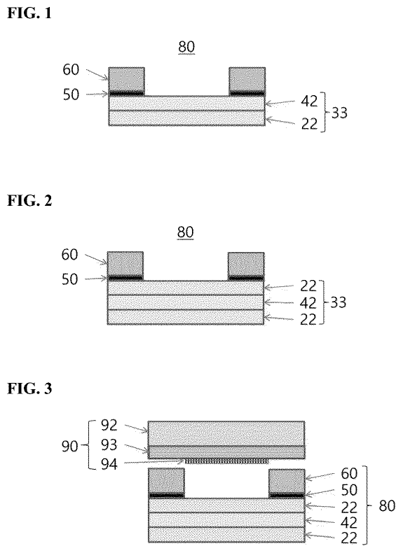

FIG. 1 is a cross-sectional view showing a pellicle according to one implementation example of the present disclosure, and FIG. 2 is a cross-sectional view showing a pellicle according to another implementation example of the present disclosure.

According to FIGS. 1 and 2, a pellicle 80 has a shape in which a pellicle film 33, a frame 60 that supports the pellicle film 33, and a binder layer 50 that attaches them to each other are combined together.

Since the pellicle film 33 has a high EUV transmittance and rises to a high temperature during transmission of the EUV, it should have an excellent high-temperature durability and film strength enough to endure a pressure difference that occurs through a vacuum process in a EUV exposure system.

In particular, a crystallized silicon (c-Si) layer 22 is silicon crystallized by electron beam irradiation, and shows crystallization peaks on surfaces of (111), (220), and (311) in accordance with an X-ray diffraction (XRD) analysis, and unlike 480 cm⁻¹ that represents an amorphous silicon, the crystallized Si shows a Raman shift at 520 cm⁻¹ that represents the crystallization in a Raman analysis.

The c-Si layer 22 has a thickness of 10 nm to 50 nm, and can secure high transmittance by the EUV.

In this case, the pellicle film 33 may be any one of c-Si/graphene, graphene/c-Si, c-Si/SiC/graphene, graphene/SiC/c-Si, c-Si/graphene/c-Si, graphene/c-Si/graphene, c-i/SiC/graphene/SiC/c-Si, and graphene/SiC/c-Si/SiC/graphene structures.

As an example, the pellicle film 33 has a multilayer thin film structure that is a structure in which the crystallized silicon (c-Si) 22 and a graphene layer 42 are heterojunctioned.

In particular, in an exposure system using a large amount of hydrogen (H₂) gas during the process, chemical stability for the hydrogen gas should be considered. As an example, since carbon series materials show the properties of being etched by the hydrogen gas, it is not preferable that the carbon series unit thin film becomes the outermost thin film in the pellicle multilayer thin film structure and is exposed to an atmosphere of coming in contact with the hydrogen.

Accordingly, as in FIG. 2, it is more preferable that the pellicle film 33 has a multilayer thin film structure that is a structure in which the crystallized silicon (c-Si) 22/graphene layer 42/crystallized silicon (c-Si) 22 are heterojunctioned.

Through this, the low mechanical properties of the crystallized silicon in the related art may be structurally supplemented by the strong mechanical properties of the graphene layer, and thus an elongation of the graphene layer and strong heat diffusion speed can be simultaneously secured.

On the other hand, while the crystallized silicon and the graphene are formed by the electron beam irradiation, a SiC compound may be formed by mutual diffusion on the Si-C interface, and this may increase the energy and irradiation time (flux) of the electron beam irradiation, resulting in that the thickness thereof can be controlled.

The total thickness of the pellicle film 33 may be equal to or larger than 5 nm and equal to or smaller than 100 nm, and preferably, it may be equal to or larger than 5 nm and equal to or smaller than 50 nm. As the thickness becomes thinner, a pellicle film having a higher EUV transmittance can be obtained.

The multilayer thin film and the frame 60 for structurally supporting this are fixed by the binder layer 50, and as the binder layer 50, a material having an excellent bonding force may be used. In order to facilitate the bonding, the binder layer 50 may be composed of the multilayer thin films, and due to the diffusion bonding of the multilayer thin films, the pellicle film 33 can be firmly fixed to the support frame.

### Reticle

FIG. 3 is a cross-sectional view showing a mounting state of a pellicle 80 according to one implementation example of the present disclosure that is combined in front of a reticle in order to hide the reticle 90.

Referring to FIG. 3, the reticle 90 is composed of: a high-purity quartz substrate 92; an EUV mirror layer 93 composed of a multilayer thin film on which 80 layers of Mo/Si layers for reflecting the EUV are repeated and a final capping layer for protecting the Mo/Si layers; and a semiconductor pattern layer 94 on which the EUV mirror layer 93 configured on a lower part is exposed according to a pattern shape by etching the semiconductor pattern by engraving after stacking a buffer layer on the mirror layer and the EUV absorption layer thereon.

In order to block particles from sticking on the engraved and exposed semiconductor pattern in the EUV process, the pellicle 80 according to the present disclosure is located on a front surface thereof, and is used as a particle filter.

The pellicle 80 may serve to protect the reticle 90 from external pollutants (e.g., dust and tin particles). If there is no pellicle, foreign substances may be attached to the semiconductor pattern of the reticle 90, and may cause a defective product problem in the EUV lithography process.

In the present specification, although the EUV light indicates light in the EUV wavelength region that is equal to or larger than 5 nm and equal to or smaller than 30 nm, the current EUV wavelength being commercially used is the wavelength of 13.5 nm made from the plasma with tin (Sn) particles input thereto.

In the exposure process, since the EUV exposes a pattern formed on the reticle 90 through reflection on a wafer on which a resist film is formed, a latent image pattern is formed on the resist film, and a resist pattern is formed on the wafer through a development process. However, if foreign substances, for example, particles, exist on the reticle, the foreign substances are transferred onto the wafer together with the pattern, and this may cause a pattern defect.

Since the pellicle 80 manufactured according to the present disclosure protects the reticle 90 from the foreign substances, and has high transmittance for the EUV and excellent thermal durability for the EUV, the pellicle has the strength enough to endure the pellicle manufacturing process or the atmospheric pressure to vacuum process in the EUV exposure system.

### Pellicle Manufacturing Method

The pellicle is to prevent pollution of the reticle (or photo mask) that is used in the exposure process, and is composed of a structure in which a pellicle film is attached to a support frame through a binder layer. In case that a multilayer in which c-Si and a graphene layer are heterojunctioned is used as the pellicle film, the effect is very good. However, in a general process for manufacturing a multilayer thin film of the c-Si and the graphene layer, a process of several complicated steps is performed, in which the c-Si and the graphene layer are separately manufactured and then are laminated, or the graphene layer is formed after an amorphous silicon crystallization process. In particular, in case of the graphene layer, it is difficult to achieve a large area thereof.

The present disclosure proposes a method capable of performing a large area process, which can not only facilitate a process control with almost no defect in an obtained multilayer thin film while simplifying the process of manufacturing a pellicle film including a multilayer thin film but also solve the problem limited to a small area in the related art.

Specifically, manufacturing of the pellicle includes the following steps:

(S1) forming a multilayer including a carbon layer, a metal catalyst layer, and an amorphous silicon layer on a substrate:

(S2) finally forming a multilayer thin film in which the c-Si layer and a graphene layer are heterojunctioned by simultaneously or sequentially performing steps of crystallizing the amorphous silicon layer with changing the amorphous silicon layer to a c-Si layer while a surface of the amorphous silicon layer is heated through irradiation of an electron beam thereto and the heat is diffused downward, diffusing carbon of the carbon layer by making the carbon of the carbon layer come up to an interface of the c-Si/metal catalyst layers through the metal catalyst layer, and then making the come-up carbon form a graphene at the interface:

(S3) performing diffusion bonding through a binder layer by making a support frame come in face-to-face contact with the binder layer on an outer periphery of the multiplayer after forming the binder layer on the outer periphery of the multilayer and forming the binder layer also on a surface of the face-to-face support frame; and

(S4) lifting off the multilayer thin film attached to the frame from the substrate.

In addition, after the step (S4), the method further includes the steps of:

(S5) forming any one or more of the amorphous silicon layer and the carbon layer on a bottom surface on an opposite side of the frame of the multilayer thin film attached to the frame; and

(S6) forming any one or more of the c-Si layer and the graphene layer on the bottom surface by irradiating the bottom surface with the electron beam.

Through the above-described steps, according to the present disclosure, the pellicle film having an asymmetric structure of c-Si/graphene, graphene/c-Si, c-Si/SiC/graphene, and graphene/SiC/c-Si, being bonded to the frame is competed.

Through the additional steps, the pellicle film having a symmetric structure of c-Si/graphene/c-Si, graphene/c-Si/graphene, c-Si/SiC/graphene/SiC/c-Si, and graphene/SiC/c-Si/SiC/graphene, being bonded to the frame is completed.

The process in which the amorphous silicon layer is crystallized into the c-Si layer and the carbon layer is diffused to the graphene layer to be crystallized may be performed by a combination of the multilayer film stacking process on the substrate and the electron beam irradiation process, and the diffusion bonding of the pellicle film deposited on the substrate to the support frame for fixing the pellicle film, and lift-off process for separating the substrate and the pellicle from each other should be necessarily performed. The multilayer film stacking, electron beam irradiation, diffusion bonding, and lift-off process can be variously changed depending on the structure of the pellicle film to be manufactured.

Hereinafter, the respective steps will be described in detail.

### (S1) Multilayer Film Stacking Process

First, the step of forming a multilayer film including an amorphous silicon layer, a metal catalyst layer, and a carbon layer on a substrate is performed.

In this case, the multilayer film may be one multilayer film selected from the group consisting of an amorphous silicon layer/metal catalyst layer/carbon layer, an amorphous silicon layer/carbon layer/metal catalyst layer, a carbon layer/metal catalyst layer/amorphous silicon layer, a carbon layer/amorphous silicon layer/metal catalyst layer, a metal catalyst layer/carbon layer/amorphous silicon layer, and a metal catalyst layer/amorphous silicon layer/carbon layer.

The substrate may be any one of an inorganic matter, such as glass, quartz, pyrex, alumina, zirconia, and sapphire; an organic matter, such as polyethylene naphthalate, polyethersulfone, polyimide, polycarbonate, polytetrafluoroethylene, polyethylene terephthalate, polystyrene, polyvinyl chloride, polyvinyl pyrrolidone, polyethylene, polydimethylsiloxane, polymethyl methacrylate, and rubber, a metal plate, such as thin plate stainless, thin plate nickel, thin plate copper, thin plate Al, and invar thin plate; and an opaque inorganic substrate, such as Si, Ge, GaN, GaAs, InP, InSb, InAs, AlAs, AlSb, CdTe, ZnTe, ZnS, ZnSe, CdSe, CdSb, GaP, and SiC.

The existing process by CVD or carbonization for manufacturing the graphene thin film requires a high-temperature process and there is a limit in using the substrate. However, according to the electron beam irradiation process according to the present disclosure, it is possible to limit the temperature being transferred to the substrate in accordance with heating of the surface only, and thus there is no limit in using the substrate.

The substrate should be separated from the pellicle in the subsequent lift-off process, and in this case, preprocessing may be performed for smooth separation.

The preprocessing of the substrate is performed through plasma implantation onto the substrate, hydrophobic plasma processing, or separation layer deposition, or a combination thereof.

In the plasma implantation, plasma is made on the substrate by using gases having a small atomic radius, such as hydrogen and helium, (+) gas ions having energy are implanted onto the substrate by giving energy of several hundreds of eV to several tens of MeV to the plasma, and the implanted gas is pushed out from the substrate by diffusion (heat application) to cause the substrate to be separated from the pellicle.

The hydrophobic plasma processing is to perform hydrophobic processing on the surface of the substrate, and is performed alone or after the plasma processing. The surface hydrophobic processing may be performed by using the atmospheric pressure plasma or vacuum plasma through mixing of C₂F₂, C₂F₄, C₂F₆, and C₃F₈, or preferably, C₄F₈ gas and He gas so that the surface of the substrate becomes hydrophobic and thus the pellicle is well separated after the (+) ion implantation irradiation is completed.

The separation layer is a layer from which gases can erupt when the temperature is increased, and separation occurs between the substrate and the pellicle by the erupting gas. The separation layer may be a layer from which H, O, N gases can erupt by heating, such as CuN, CuO, and Si:H.

The amorphous silicon layer can be made through a deposition process, and as the deposition process, plasma enhanced chemical vapor deposition (PECVD), chemical vapor deposition (CVD), low pressure chemical vapor deposition (LPCVD), RF/DC sputtering, ion beam deposition (IBD), vacuum deposition, electron beam deposition, ion plating, or pulse laser deposition process may be used.

In this case, the thickness of the amorphous silicon layer is formed in the range of 5 nm to 50 nm. The thickness range is in consideration of the final thickness of the c-Si formed by the electron beam irradiation, and means an appropriate thickness that can secure the optimum physical properties when being applied to the pellicle for EUV.

The metal catalyst layer may act as a catalyst not only in crystalizing the amorphous silicon layer but also in crystalizing the carbon layer to the graphene, and the metal catalyst layer may be finally removed by an etchant. Without forming of the metal catalyst layer, crystallization to the graphene is not possible.

Ni catalyst metal that forms the metal catalyst layer should have a face centered cubic (FCC) structure. As crystal structures, there are body centered cubic lattice (BCC) structure, FCC structure, and closed packed hexagonal lattice (HCP) structure, and most metals have one of the above crystal lattice structures.

By the electron beam irradiation, carbon atoms of a graphene precursor form an aromatic hexagonal C═C-bond, and in this case, the carbon atoms are absorbed onto the surface of the catalyst metal to be grown to a graphene thin film. In case that the surface energy of the catalyst metal is unstable, the absorption speed of the carbon atoms differs to bring the result in that the carbon atoms are carbonized other than graphened. In the FCC structure of the Ni catalyst metal, the surface (111) has the most stable and uniform surface energy, and thus the carbon atoms are evenly settled to make the graphene thin film stably grown.

Preferably, in case that the metal catalyst layer is made of Ni, a metal having the FCC structure is desirable, and other catalyst metals include one or more single metals or alloys selected from the group consisting of Ti, Al, Zn, Co, Cu, Pt, Ag, and Au.

The thickness of the metal catalyst layer is not specially limited, but may be 0.1 nm to 10 nm.

In the present disclosure, the forming of the metal catalyst layer is not specifically limited, and any method capable of forming a uniform thin film over the entire substrate may be used. As an example, the above-described dry deposition process may be used.

The carbon layer according to the present disclosure is a layer that can be changed into the graphene by the electron beam irradiation, and may be manufactured through a wet process or a dry process.

The carbon layer through the wet process means a graphene cured coating film obtained by coating and curing the graphene precursor solution, and the graphene precursor layer through the dry process means a carbon deposition layer formed by CVD, PECVD, sputtering, or vacuum deposition. The carbon layer is changed into the graphene by the electronic beam irradiation later, and the thickness of the graphene can be easily adjusted by the wet process and the dry process, so that the thickness of the finally obtained graphene layer can be easily adjusted. In addition, in case of the wet process, the carbon layer can be produced with a large area, and thus there is an advantage in that the large-area graphene layer can be easily formed as compared with that in the related art.

In manufacturing the carbon layer through the wet process according to one implementation example of the present disclosure, the graphene precursor may be produced by applying, drying, and then curing the graphene precursor solution including the graphene precursor and a solvent.

The graphene precursor is a polymer, and any one that has the graphene structure by the electron beam irradiation can be the graphene precursor. Representatively, the graphene precursor can be one selected from the group consisting of polyimide, polyacrylonitrile, polymethyl methacrylate, polystyrene, rayon, lignin, pitch, borazine oligomer, and a combination thereof. Among the above graphene precursors, aromatic hydrocarbon series, that is, polyimide, is desirable so that an aromatic hexagonal C═C-bond can easily occur by the electron beam irradiation. Further, it is preferable that the polymer is oligomer so that the subsequent curing process can be performed.

In this case, it is possible to adjust the state and the kind of the graphene finally obtained by composition of the graphene precursor. As an example, in case of the polyimide or PMMA, it is possible to manufacture a graphene thin film having an excellent conductivity, and in case of the borazine oligomer, it is possible to manufacture a white graphene thin film.

As an available solvent, any one that can adjust viscosity in a predetermined range through sufficient dissolution of the graphene precursor can be used. This solvent may differ depending on the composition or molecular weight of the graphene, that is, the polymer, and as an example, the solvent may include one, two, or more selected from the group consisting of dimethylformamide (DMF), formaldehyde, chloroform, dimethylacetamide (DMA), pyridine, benzopyridine, benzene, xylene, toluene, dioxane, tetrahydrofuran (THF), diethyl ether, dimethyl sulfoxide (DMSO), and n-methyl-2-pyrrolidone (NMP).

As needed, the graphene precursor solution may further include an additive for adjusting dispersibility, applicability, and viscosity and/or a dopant for the purpose of doping. The kind and the content range thereof are not specially limited in the present disclosure, and may be properly selected by those skilled in the art.

After a normal wet coating method is performed with respect to the graphene precursor solution on the metal catalyst layer, a carbon layer is formed through drying and curing.

In this case, in order to facilitate the coating and to form a uniform dry coating film, the viscosity of the graphene precursor solution is limited. Preferably, the viscosity can be within the range of 100 cps to 10 cps, and as the viscosity becomes thinner, the coating thickness is lowered. If the density is below the above range, it is required to pass through coating processes several times in order to form the graphene precursor dry coating film with a predetermined thickness, and thus it may be difficult to form the uniform dry coating film. In contrast, if the viscosity is too high, the physical properties of the entire carbon layer that is obtained after the subsequent curing process may be non-uniform, and thus the graphene precursor solution is properly used within the above-described viscosity range.

The wet coating method may be any one method of roll coating, spray coating, impregnation coating, spin coating, gravure coating, knife coating, bar coating, slot die coating, or screen printing, and among them, the spray coating, spin coating, or roll coating method in case of a continuous process may be used to facilitate the process and to form the uniform coating film.

After the coating, the solvent is removed through drying. The drying temperature and method may differ depending on the kind of the solvent being used, and hot air drying or induction heating drying may be normally used at temperatures of 30° C. to 90° C., 35° C. to 85° C., and 40° C. to 80° C., and as needed, decompression may be performed.

After the drying, the dry coating film of the graphene precursor on the metal catalyst layer becomes the carbon layer through curing with heat applied thereto. The temperature for the curing differs depending on the kind of the polymer of the graphene precursor, and in case of the polyimide, the curing is performed at 400° C.

The carbon layer obtained after the curing may be in the range of 5 nm to 200 nm, and preferably, in the range of 0.5 nm to 20 nm. The thickness of the carbon layer participates in the thickness of the total graphene layer that is manufactured by the electron beam. If the thickness is too thin, it is unable to form the graphene with a stable structure, whereas if the thickness is too thick, graphitized or multilayered graphite may be formed.

Further, the carbon layer through the dry process according to one implementation example of the present disclosure may be a carbon deposition layer, and may be deposited in methods of chemical vapor deposition (CVD), plasma enhanced chemical vapor deposition (PECVD), sputtering, graphite ion beam deposition, and physical vapor deposition. In this case, as the carbon source, a hydrocarbon gas including CH₄, C₂H₂, C₂H₄, and C₂H₆ may be used, and in case of the PVD, a graphite target is singly used, or is used commonly with the hydrocarbon gas. The carbon deposition layer may be formed without any separate curing process, and has the above-described thickness range of the carbon layer.

The above-described multilayer film including the amorphous silicon layer, the metal catalyst layer, and the carbon layer has the heterojunctioned structure of the c-Si/graphene layer through the subsequent process.

### (S2) Electron Beam Irradiation Process

Next, the step of forming a c-Si/graphene pellicle film having a multilayer thin film structure in which the c-Si layer and the graphene layer are heterojunctioned is performed by simultaneously performing crystallization into the c-Si layer through electron beam irradiation, diffusion through the metal catalyst layer of the carbon as the Si/catalyst interface, and graphene formation on the interface.

The electron beam irradiation is performed in order to manufacture the multilayer thin film structure in which the C-Si layer and the graphene layer are heterojunctioned. The electron beam irradiations may be performed to form the c-Si layer and the graphene layer, respectively, or may be performed at the same time to simultaneously form the c-Si layer and the graphene layer. As an example, the amorphous silicon may be crystallized simultaneously with the graphene crystallization after the multilayer thin film is formed, or as needed, the crystallization of the silicon only may be pre-performed immediately after the silicon deposition.

As the previously known amorphous silicon crystallization methods, various methods, such as solid phase crystallization (SPC), laser induced crystallization (LIC), metal induced crystallization (MIC), and joule heating induced crystallization (JIC), are used, but there are differences in thin film state between them after the crystallization.

The c-Si formed by the electron beam irradiation is easily crystallized in comparison to the c-Si formed by the existing laser beam irradiation, and in particular, the metal induced crystallization has an advantage in that the crystallization is easily induced. In addition, in comparison to the c-Si formed by the laser beam irradiation, the c-Si formed by the electron beam irradiation has an advantage in that hill-lock does not exist on the grain boundary or the surface, and since the grain boundary becomes a path through which propagation of cracks is transferred, the crystallization film by the electron beam irradiation may have an advantage of being not easily broken in comparison to the crystallization film by the laser beam irradiation when a thin film is lifted off and is free-standing inside the frame.

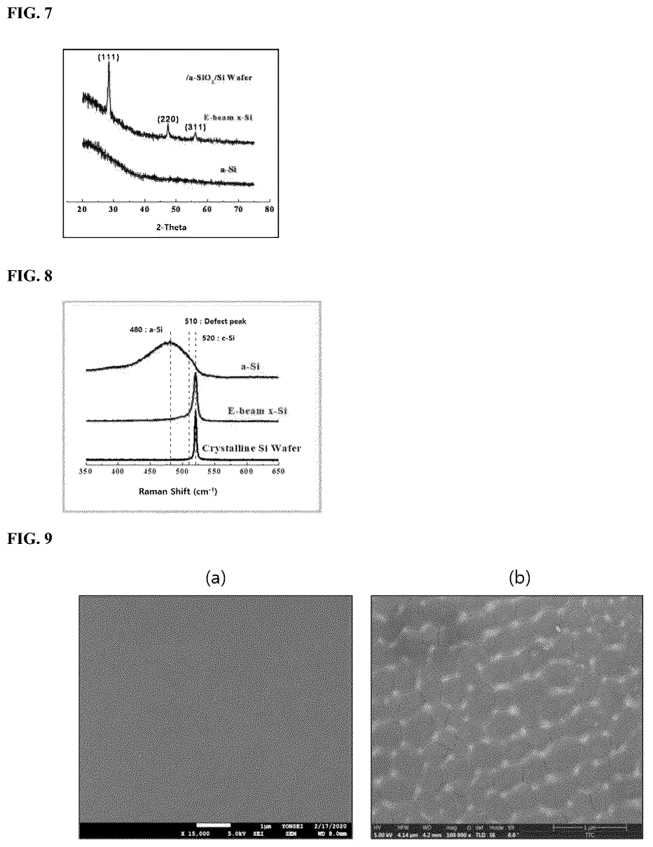

FIG. 7 shows an X-ray diffraction pattern of an electron beam irradiated c-Si at room temperature, and it can be known that crystallization peaks appear on surfaces (111), (220), and (311) by the electron beam irradiation.

FIG. 8 shows a Raman spectrum, in which in case of c-Si by electron beam irradiation, a sharp peak is shown at a different location from 480 cm⁻¹ representing amorphous silicon, and a peak is shown at 520 cm⁻¹ representing similar crystallization to that of Si wafer, so that it can be known that crystallization of silicon occurs.

FIG. 9 shows a scanning electron microscope (SEM) image showing a thin film state, and it can be known that c-Si crystallized by laser irradiation has a grain boundary that occurs as the c-Si is melted and solidified with hill-lock existing on the surface, whereas in case of c-Si crystallized by electron beam irradiation, it can be known that a high-quality thin film having not grain boundary has been formed.

In FIG. 9, crystallization (b) of amorphous silicon by laser irradiation has a grain boundary of a several μm size, but c-Si (a) crystallized by the electron beam irradiation does not have the grain boundary of the μm size. If a crack that starts on one side of a pellicle occurs when an external force or impact occurs, and in particular, there is a difference in vacuum pressure between front and back surfaces of the pellicle, the pellicle destruction occurs through propagation of the crack along the grain boundary, and thus the crystallized silicon c-Si having no grain boundary, which is made by the electron beam irradiation, can be used as a material of excellent properties which can increase the strength of the pellicle and increase the transmittance of the EUV.

Further, if the electron beam is irradiated on the amorphous silicon/metal catalyst layer/carbon surface, the metal of the metal catalyst layer exists in a solid-solution state, and as the carbon in the carbon layer moves through diffusion, a carbon precipitation layer is made on the interface of the metal catalyst layer-silicon that comes in contact with the amorphous silicon layer. This precipitation layer is changed into the graphene by the metal that acts as the catalyst that forms the graphene structure. In this case, the grown graphene is obtained in the form of a precise thin film that does not include pores or defects, and the growth occurs uniformly from the surface of the metal catalyst layer at relatively the same speed, so that the graphene layer having high smoothness can be obtained. The metal catalyst layer forms the metal-carbon (e.g., Ni—C) bond during the electron beam irradiation, and flies away through automatic high-temperature sublimation, or is removed by etching, so that the metal catalyst layer does not exist on the surface of the final pellicle film.

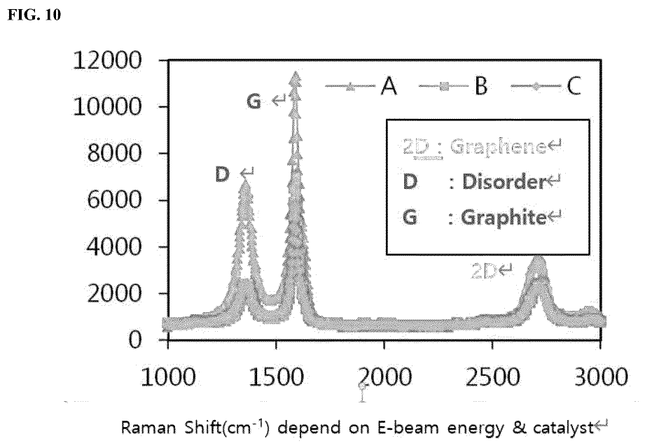

FIG. 10 shows a Raman spectrum of the graphene created by irradiating a carbon layer that comes in contact with a catalyst with an electron beam, and it can be known that a graphene thin film has been formed through identification of 2700 cm⁻¹:2D peak that represents the graphene together with 1300 cm⁻¹:D peak and 1580 cm⁻¹:G peak.

In particular, according to various embodiments of the present disclosure, it is possible to form the c-Si layer and the graphene layer at the same time through the electron beam irradiation. In case of separately forming the c-Si layer and the graphene layer, separate different processes should be performed, and this causes problems in that the process is cumbersome, it is difficult to form a two-layer bond structure since the c-Si layer and the graphene layer remain as complete crystallization layers when being formed, and the cost is increased. However, in the present disclosure, through the electron beam irradiation for changing the graphene precursor into the graphene, the crystallization of the amorphous silicon is simultaneously performed, and thus the problems of the processes and costs in the related art can be solved.

According to the electron beam irradiation process, the processing time can be relatively shortened through adjustment of energy and flux, and the thin film of enhanced properties can be obtained at extremely faster speed than the speed of the general heat treatment method. Further, without separate heat treatment, that is, without applying heat to the substrate, the surface heating can be performed by the electron beam irradiation on the surface side, and thus the substrate, of which the use is limited due to breaking or bending problems caused by heat in the related art, can be unlimitedly used, and relatively low costs are required in the process.

In addition, by variously changing the structure of the multilayer thin film, it is possible to variously combine the construction of the finally obtained pellicle film.

The electron beam irradiation is performed in a known vacuum chamber in which the electron beam irradiation is possible. In the vacuum chamber, a support is disposed therein, a substrate is mounted on the support, and an electron beam source for the electron beam irradiation is disposed in a direction in which the substrate is viewed.

In order to generate the electron beam, a field emission method for extracting electrons by applying a high negative voltage to a sharp tip, a thermionic method for making electrons protrude from a surface of a filament through heating of the filament, such as tungsten and LaB₆, or a plasma extraction method for extracting and accelerating electrons by applying a voltage to the plasma simultaneously with shielding of the plasma with a grid may be used.

Among them, the plasma extraction method can adopt a rod type linear source, and by scanning this in a vertical direction of a large substrate, a large area can be uniformly processed. In this case, in order to make the plasma, various kinds of power sources, such as LF, MF, HF, RF, UHF, and microwave, can be used in accordance with AC frequencies, and plasma having a high pressure such as atmospheric plasma may be used.

The electron beam irradiation may be performed while transporting the support at a predetermine speed in a state where the electron beam source is fixed, or transporting the electron beam source in a state where the support is fixed. Preferably, the former is advantageous from the viewpoint of the process control.

In this case, one or more electron beam source may be used, and for a large-area pellicle film, a plurality of electron beam sources may be used in a state where they are disposed in series or in parallel.

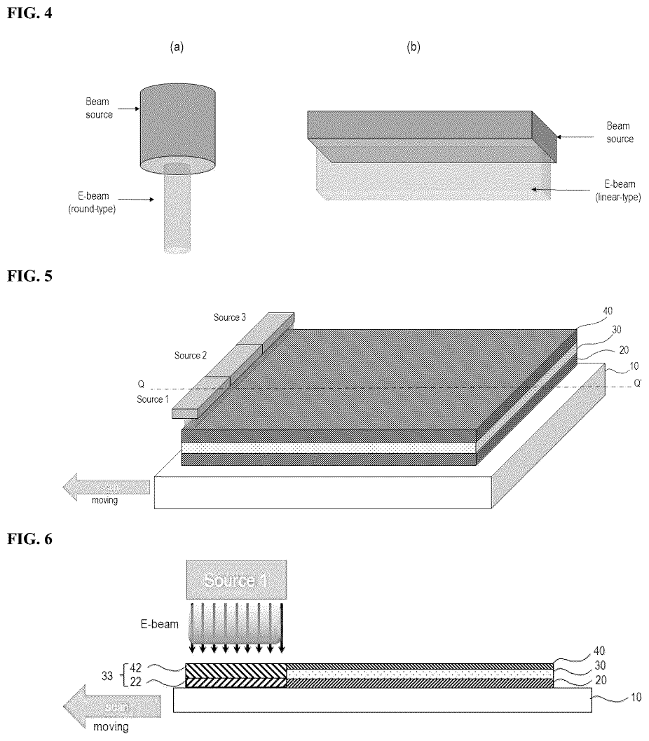

FIG. 4 is a schematic diagram showing a beam shape of an electron beam source. Depending on the cross-sectional shape (e.g., spot) of the electron beam source, the electron beam source may be a round source ((a) of FIG. 4) that generates a round electron beam or a linear source ((b) of FIG. 4) that generates a linear electron beam having the different ratio of width and height, and it is possible to form a large-area pellicle film through their various dispositions. Preferably, as the electron beam source, a linear gun in the form of a long cuboid having a length that is similar to the width of the substrate may be used.

FIG. 5 is a schematic diagram showing irradiation of a linear electron beam onto a substrate according to one implementation example of the present disclosure, and FIG. 6 is a schematic diagram showing Q-Q′ cutting surface of FIG. 5. In this case, although it is illustrated in the drawing that electron beams are irradiated onto a predetermined area only, the electron beams fly while spreading out to some extent during the actual electron beam irradiation, and since the electron beams fly with the entire flight space occupied, the electron beams are simultaneously irradiated onto the predetermined area of the opposite substrate.

Referring to FIG. 5, after three linear electron beam sources source1, source2, and source3 are disposed in series on a substrate on which amorphous silicon layer/metal catalyst layer/carbon layer are sequentially formed, electron beams are irradiated over the entire substrate through transporting of the electron beam sources in one side direction while irradiation of the electron beams in a state where the substrate is fixed, and thus a pellicle film on which the c-Si/graphene layer are heterojunctioned can be formed in a large area. By the series connection of the linear beam sources as in FIG. 6, the large-area processing becomes possible, and the processing speed can be heightened through connection of other linear beam sources in parallel.

Further, three electron beam sources are disposed in series so that the electron beams can be irradiated all over the width of the substrate. In this case, as in FIG. 6, the electron beams are irradiated over the entire substrate through transporting of the electron beam sources in one side direction, and after the irradiation, the carbon layer is changed into the graphene layer, and the amorphous silicon layer is changed into the c-Si.

The method illustrated in FIGS. 5 and 6 is a scan method while transporting the electron beam sources through series disposition of three linear electron beam sources. This method belongs to one implementation example of the present disclosure, in which the number and the form of the electron beam sources may differ depending on the size of the substrate, and the disposition of the electron beam sources may be made in series, in parallel, or in a mixed manner. Further, although the scan method while moving the electron beam sources has been described in the above example, a method for transporting the substrate in one side direction in a state where the electron beam sources are fixed.

During the electron beam irradiation, the transport speed of the electron beam sources or the substrate can be set to provide time in which the c-Si layer/graphene layer are sufficiently formed. That is, as the thickness of the amorphous silicon layer and the carbon layer becomes thinner, or energy of the applied electron beam becomes higher, the transport speed may be increased. More specific conditions may be properly selected and changed by those skilled in the art.

The electron beam irradiated onto the substrate is accelerated to have kinetic energy of 50 eV to 50 keV, and preferably, 1 keV to 10 keV, by the voltage being applied, and is irradiated onto a processing area on the substrate.

The electron beam irradiation process is performed under the existence of an inert gas, and in this case, it is preferable that the inert gas is one or two or more selected from nitrogen, helium, neon, argon, xenon, or their mixed gas, but is not limited thereto.

As described above, the layer stacking, drying, curing, and electron beam irradiation steps including the electron beam irradiation of the present step may be automatically performed in a row through a roll-to-roll process, or may be performed to be divided per step. As described above, one or more steps of the method disclosed in the present disclosure may be generated automatically, for example, through the use of a computer-controlled automatic processing line. As an example, after the linear electron beam sources are mounted on the roll-to-roll vacuum chamber system, a large-area graphene process is technically possible through the continuous line.

In addition, in order to remove a very small amount of amorphous carbon layer existing on the graphene thin film after the electron beam irradiation in the above step, a process of irradiating the surface with hydrogen beams made through plasma etching using hydrogen or hydrogen plasma activation may be further performed.

After the electron beam irradiation, the metal catalyst layer may be removed through an etching process.

Meanwhile, through the control of the present electron beam irradiation process, the SiC layer is formed on the Si/carbon interface by reaction of Si and carbon. The formation and the thickness of the SiC layer can be controlled by adjusting the irradiation time of the electron beam. Through this, the pellicle film can be produced in the form of including SiC, such as c-Si/SiC/graphene, c-Si/SiC/graphene/SiC/c-Si, or graphene/c-Si/SiC/graphene.

As an example, the multilayer thin film is made in a mirror structure through combination of the multilayer thin film deposition, the electron beam irradiation, and the etching order of the metal catalyst layer disposed outermost, and the forming of the SiC layer on the Si/C interface can be adjusted through additional adjustment of the electron beam irradiation time.

### (S3) Diffusion Bonding Process

Next, after a binder layer is formed on an outer periphery of the multilayer film, and a support frame is made to come in contact with the substrate, diffusion bonding is performed through the binder layer.

The diffusion bonding process means a bonding process of a pellicle film and the support frame for fixing the pellicle film to each other.

First, the binder layer is formed on the outer periphery of the pellicle film (or multilayer film before electron beam irradiation).

The binder layer is made of a material that is easy to be bonded in accordance with the material of a support frame, and is formed with a thickness above a certain level in the range of 0.1 nm to 100 nm so as to maintain the bonding strength after the final boding in the diffusion bonding process.

As needed, a buffer layer may be additionally formed to come in contact with the binder layer.

Next, in order to fix the pellicle film to the substrate formed with the pellicle film, a buffer/binder layer is deposited to face the surface of the facing support frame, and then the diffusion bonding is performed through the binder layer.

It is preferable that the support frame is made of a silicon wafer, Ti metal plate, aluminum alloy, or ceramic material, has low thermal expansion at high temperatures, should not be deformed at high temperatures, and has a melting point that is equal to or higher than 1000° C. over 800° C.

It is preferable that the ceramic support frame is made of alumina and zirconia as main ingredients, and includes black ceramic partially including manganese, chrome, and carbon as a coloring agent to be colored as black. This is to minimize reflection of an exposed light on the support frame.

The diffusion bonding (cladding) is to make bonding between the binder layer and the support frame, and is a bonding technology using diffusion of atoms occurring between bonding surfaces by making the binder layer and the support frame come in close contact with each other. The diffusion bonding is characterized by little thermal stress or deformation after the bonding and little deterioration of the material by an organizational change, and has an advantage in that bonding of not only homogeneous materials but also heterogeneous materials and bonding of a complicated shape are possible.

In the present disclosure, the pellicle film can be firmly fixed to the support frame through the diffusion bonding between the binder layer and the support frame. The diffusion bonding may be performed in a manner of pressing the binder layer

and the support frame to the extent that plastic deformation does not occur as much as possible at a temperature that is equal to or lower than the melting point of the support frame, and may differ depending on the material of the binder layer and the support frame.

The binder layer includes a low-temperature melting metal; an eutectic alloy of which the melting temperature is lowered while any one of Zn, Ga, In, Sn, or Au is alloyed together with any one of Al, Si, Ti, Cr, Mn, Fe, Co, Ni, Cu, Zr, Nb, Mo, Te, Ru, Pd, Ag, or Pt; a general alloy; and a multilayer film selected from at least one of their oxide, nitride, carbide, and boride. The binders are formed on the multilayer film circumference and both side surfaces of the support frame, and are diffusion-bonded.

According to one implementation example, in case of the frame of the Si material, the diffusion bonding may be performed by applying the pressure of 0.1 Mpa to 1.0 Mpa at a temperature of 300° C. to 600° C. with respect to a eutectic alloy buffer layer made of Ti/Au. In this case, if proper temperature and pressure are not applied, the strength is low on a bonding part, and thus the pellicle film may be detached from the support frame in the process of mounting the pellicle on the reticle or in the process before or after the mounting process. Accordingly, the temperature and the pressure are properly adjusted within the above range.

### (S4) Lift-Off Process

Next, a process of lifting off the pellicle from the substrate is performed.

The lift-off is a process of separating the pellicle from the substrate.

The lift-off process may be performed through a heating method using a heater or an RTA halogen lamp on the rear surface of the substrate or a heating method through electron beam or laser irradiation. Through the heating of the rear surface of the substrate, the pellicle separation occurs due to a difference in thermal expansion coefficient between the substrate and the c-Si or between the substrate and the graphene. Accordingly, a method in which the temperature of the substrate is abruptly increased may be preferred.

According to an embodiment of the present disclosure, the lift-off process is performed by irradiating the rear surface of the substrate with the electron beam of 2 keV to 50 keV for 30 seconds to 5 minutes. The electron beam is the same as the electron beam in the previous step (S2), and the lift-off process can be performed in a method for scanning the entire substrate by using the linear electron beam. Such a method has an advantage of being easier to separate the pellicle film having a large-area size.

In particular, in case that gas particles are stuck onto the surface of the substrate through plasma implantation of the substrate with hydrogen or helium gases and thus the gas particles are erupted out of the interface with the pellicle simultaneously with heating of the substrate, or in case that the surface of the plasma-implanted substrate is chemically treated to facilitate the peeling thereof through additional plasma hydrophobic processing on the substrate, or in case that the separation layer, such as a CuO, CuN, or Si:H layer, is formed on the interface with the substrate, the hydrogen, helium, nitrogen and oxygen gases are separated from the layers through heating of the rear surface of the substrate, and thus the pellicle separation becomes easier between the substrate and the c-Si or between the substrate and the graphene.

The lift-off process is very important especially in case of forming the pellicle film in a large area. The separation of the substrate and the pellicle layer from each other may be easy in case that the size of the pellicle film is small, but in case of forming the pellicle film in a large area, there may be a risk that a part of the pellicle film is split or damaged in the lift-off process. Accordingly, in case of performing the heat treatment and the electron beam or laser irradiation together with the preprocessing of the substrate on the large-area pellicle film, the high-quality pellicle film can be separated and retrieved as it is after the lift-off process.

The pellicle retrieved through the above step has the shape in which the pellicle film is supported by the support frame, and in this case, the pellicle film has the structure in which the c-Si/graphene is heterojunctioned.

Further, during the electron beam irradiation, it is possible to manufacture the pellicle in which the c-Si/SiC/graphene is bonded through extension of the irradiation time.

### Additional Process: Amorphous Silicon Deposition and Electron Beam Irradiation Step

In addition, after the step (S4), by performing an additional process, it is possible to produce the pellicle having a different form, as an example, having a multilayer thin film with a symmetrical structure of c-Si/graphene/c-Si, graphene/c-Si/graphene, c-Si/SiC/graphene/SiC/c-Si, and graphene/SiC/c-Si/SiC/graphene.

According to one implementation example, it is possible to produce the pellicle with various structures by additionally performing, after the step (S4), the steps of: (S5) forming any one or more of the amorphous silicon layer and the carbon layer on a bottom surface on an opposite side of the frame of the multilayer thin film attached to the frame; and (S6) forming any one or more of the c-Si layer and the graphene layer on the bottom surface by irradiating the bottom surface with the electron beam.

As an example, in the step (S5), the pellicle of the c-Si/graphene/c-Si structure is produced by depositing the amorphous silicon layer on the graphene of the multilayer thin film.

As another example, in the step (S5), the pellicle of the graphene/c-Si/graphene structure is produced by depositing the carbon layer on the c-Si layer of the multilayer thin film.

As still another example, in the step (S6), through extension of the electron beam irradiation time, the SiC layer can be further formed between the c-Si layer and the graphene layer, and the pellicle of the c-Si/SiC/graphene/SiC/c-Si or graphene/SiC/c-Si/SiC/graphene structure is produced.

As still another example, the steps (S5) and (S6) may be performed multiple times.

As still another example, in the step (S5), all of the amorphous silicon layer and the carbon layer may be formed, and in this case, a metal layer may be additionally formed.

Further, in case that the metal catalyst layer remains on the uppermost layer of the multilayer thin film before the step (S5), the metal catalyst layer is etched. As an example, the c-Si/graphene/metal catalyst layer are formed through the steps (S1) to (S4), and the metal catalyst layer formed on the graphene layer is removed through etching.

In case that the metal catalyst layer is formed with a thin thickness, it may not remain after the step (S4), whereas in case that the metal catalyst layer is formed with a thick thickness, it may remain, and the process of the step (S5) is further performed after removing the metal catalyst layer through etching.

Table 1 below is to summarize the pellicle production method proposed in the present disclosure. The processes in the table below are merely exemplary, and it is possible to produce the pellicle of various structures by changing the material of the multilayer thin film in the step (S1), the electron beam irradiation time in the steps (S2) and (S6), and the additional deposition material in the step (S5).

TABLE 1

| | (a) c-Si/graphene: one of amorphous silicon layer/metal catalyst layer/carbon layer/ | | | | | |
|---|---|---|---|---|---|---|
| | substrate, amorphous silicon layer/carbon layer/metal catalyst layer/substrate, and metal | | | | | |
| (S1) | catalyst layer/amorphous silicon layer/carbon layer/substrate | | | | | |
| Multilayer | (b) graphene/c-Si: one of carbon layer/metal catalyst layer/amorphous silicon layer, carbon | | | | | |
| film | layer/amorphous silicon layer/metal catalyst layer, and metal catalyst layer/carbon layer/ | | | | | |
| formation | amorphous silicon layer | | | | | |
| (S2) | ◯ | ◯, | ◯ | ◯ | ◯, | ◯, |
| Electron | | Irradiation | | | Irradiation | Irradiation |
| beam | | time | | | time | time |
| irradiation | | extension | | | extension | extension |
| (S3) | ◯ | ◯ | ◯ | ◯ | ◯ | ◯ |
| Diffusion | | | | | | |
| bonding | | | | | | |
| (S4) | ◯ | ◯ | ◯ | ◯ | ◯ | ◯ |
| Lift-off | | | | | | |
| (S5) | — | — | Amorphous | Carbon layer | Amorphous | Carbon layer |
| Additional | | | silicon | deposition | silicon | deposition |
| deposition | | | deposition | | deposition | |
| (S6) | — | — | ◯, c-Si | ◯, Graphene | ◯, c-Si | ◯, Graphene |
| Electron | | | formation | formation | formation, | formation, |
| beam | | | | | irradiation | irradiation |
| irradiation | | | | | time | time |
| | | | | | extension | extension |
| Pellicle | c-Si/ | c-Si/SiC/ | c-Si/ | Graphene/ | c-Si/SiC/ | Graphene/SiC/ |
| film | graphene, | graphene, | graphene/c-Si | c-Si/ | graphene/ | c-Si/SiC/ |
| structure | and graphene/ | and graphene/ | | graphene | SiC/c-Si | graphene |
| | c-Si | SiC/c-Si | | | | |

— Addition of removing process of metal catalyst layer through etching before (S3) and/or (S5)

According to the method for manufacturing the pellicle for EUV lithography according to the present disclosure as described above, since the process is very simple, and the linear electron beam with the size enough to cover the large area of the pellicle is possible, there is an advantage in that it is possible to produce the pellicle of the large-area high-throughput, in which uniform beam processing is possible over the entire area of the pellicle.

As a result, the pellicle manufactured according to the present disclosure is protective from foreign substances, and has high transmittance for the EUV, excellent durability for the EUV, and the strength enough to endure the pellicle manufacturing process or the atmospheric pressure or vacuum process in the EUV exposure system. Further, the pellicle has an advantage of being produced in the large area.

### EMBODIMENT

Hereinafter, the present disclosure will be described in detail through embodiments. However, the following embodiments merely exemplify the present disclosure, but the contents of the present disclosure are not limited by the following embodiments.

### Embodiment 1

### Pellicle of Graphene/c-Si Structure

Through the following steps, a pellicle film and a pellicle in which the pellicle film was mounted on a support frame were produced.

An amorphous silicon layer with the thickness of 40 nm was deposited through PECVD on the surface of a Si wafer on which H₂ plasma implantation processing and atmospheric hydrophobic plasma preprocessing had been performed, and then a Ni thin film with a thickness of 10 nm was formed with a metal catalyst layer through sputtering. After a graphene precursor solution (polyimide/NMP solution, 10 cps) was coated on the metal catalyst layer and dried for 10 minutes at 40° C., a graphene precursor cured coating film with a thickness of 25 nm was manufactured by performing heat curing for 20 minutes at 400° C.

After transporting of the substrate into an electron beam deposition chamber, a pellicle film in which c-Si with a thickness of 35 nm and a graphene layer with a thickness of 10 nm were heterojunctioned was formed through irradiation of an electron beam of 4 keV for 5 minutes at room temperature.

Next, a binder layer with a thickness of 20 nm was formed through sputtering using Ti metal along an outer periphery of the graphene layer that is the outermost layer of the pellicle film. Meanwhile, a binder layer made of Ti/Au metal was deposited even on an opposite frame, and then a diffusion bonding process was performed at a temperature of 600° C. and under pressure of 0.2 Mpa.

Next, a gap was made through eruption of a hydrogen gas between the c-Si that is the lowermost layer of the pellicle film and the substrate by irradiating the rear surface of the substrate with the electron beam of 4 keV for 2 minutes, and then the pellicle having a graphene/c-Si structure was produced by retrieving the pellicle through lift-off of the pellicle therefrom.

### Embodiment 2

Pellicle of c-Si/Graphene Structure

In the same manner as in Embodiment 1, the pellicle was produced in a different thin film deposition order.

After a graphene precursor solution (polyimide/NMP solution, 10 cps) was coated on the surface of a Si wafer on which H₂ plasma implantation processing and atmospheric hydrophobic plasma preprocessing had been performed, and then dried for 10 minutes at 40C, a graphene precursor cured coating film with a thickness of 25 nm was manufactured by performing heat curing for 20 minutes at 400° C. Thereafter, a Ni thin film with a thickness of 10 nm was formed with a metal catalyst layer through sputtering, and an amorphous silicon layer with the thickness of 40 nm was deposited through PECVD on the metal catalyst layer.

After transporting of the substrate into the electron beam deposition chamber, a pellicle film in which c-Si with a thickness of 35 nm and a graphene layer with a thickness of 10 nm, which was made after diffusion and movement of carbon on a catalyst layer, were heterojunctioned was formed through irradiation of an electron beam of 4 keV for 5 minutes at room temperature.

Next, a binder layer with a thickness of 20 nm was formed through sputtering using Ti metal along an outer periphery of the c-Si layer that is the outermost layer of the pellicle film. Meanwhile, a binder layer made of Ti/Au metal was deposited even on an opposite frame, and then a diffusion bonding process was performed at a temperature of 600° C. and under pressure of 0.2 Mpa.

Next, a gap was made through eruption of a hydrogen gas between the c-Si that is the lowermost layer of the pellicle film and the substrate by irradiating the rear surface of the substrate with the electron beam of 4 keV for 2 minutes, and then a multilayer thin film of c-Si/graphene/Ni was lifted off therefrom.

Then, the pellicle having the c-Si/graphene structure finally bonded to the frame was produced by removing the Ni layer through etching.

### Embodiment 3

Pellicle of c-Si/SiC/Graphene Structure

In the same manner as in Embodiment 2, a c-Si/SiC/graphene pellicle in which SiC was formed on an interface of a c-Si layer and a graphene layer was produced through extension of an electron beam irradiation time.

### Embodiment 4

Pellicle of c-Si/Graphene/c-Si Structure

Through the following steps, a pellicle film and a pellicle in which the pellicle film was mounted on a support frame were produced.

After a graphene precursor solution (polyimide/NMP solution, 10 cps) was coated on the surface of a Si wafer on which H₂ plasma implantation processing and atmospheric hydrophobic plasma preprocessing had been performed, and then dried for 10 minutes at 40C, a graphene precursor cured coating film with a thickness of 25 nm was manufactured by performing heat curing for 20 minutes at 400° C. Thereafter, a Ni thin film with a thickness of 10 nm was formed with a metal catalyst layer through sputtering, and an amorphous silicon layer with the thickness of 40 nm was deposited through PECVD on the metal catalyst layer.

After transporting of the substrate into the electron beam deposition chamber, a pellicle film in which c-Si with a thickness of 35 nm and a graphene layer with a thickness of 10 nm, which was made after diffusion and movement of carbon on a catalyst layer, were heterojunctioned was formed through irradiation of an electron beam of 4 keV for 5 minutes at room temperature.

Next, a binder layer with a thickness of 20 nm was formed through sputtering using Ti metal along an outer periphery of the c-Si layer that is the outermost layer of the pellicle film. Meanwhile, a binder layer made of Ti/Au metal was deposited even on an opposite frame, and then a diffusion bonding process was performed at a temperature of 600° C. and under pressure of 0.2 Mpa.

Next, a gap was made through eruption of a hydrogen gas between the c-Si that is the lowermost layer of the pellicle film and the substrate by irradiating the rear surface of the substrate with the electron beam of 4 keV for 2 minutes, and then a multilayer thin film of c-Si/graphene/Ni was lifted off therefrom.

Thereafter, after the c-Si/graphene attached to the frame was left through etching of the Ni layer that is the metal catalyst layer, a crystallized c-Si layer was made through deposition of amorphous silicon on an opposite graphene surface by PECVD and irradiation of the electron beam, and the c-Si/graphene/c-Si pellicle bonded to the frame was finally produced.

### Embodiment 5

Pellicle of c-Si/SiC/Graphene/SiC/c-Si Structure

In the same manner as in Embodiment 3, a c-Si/SiC/graphene/SiC/c-Si pellicle in which SiC was formed on an interface of a c-Si layer and a graphene layer was produced through extension of an electron beam irradiation time.

### Test Example 1

### Analysis of Crystalline Silicon Layer

### Crystallization Analysis of Crystalline Silicon Layer

In order to identify whether the c-Si layer was formed according to the electron beam irradiation after depositing amorphous silicon, Z-ray diffraction analysis and Raman analysis were performed.

Referring to FIG. 7, an electron beam was irradiated with energy of 4 keV after an amorphous silicon layer with a thickness of 200 nm was deposited on a Si wafer having a surface on which a natural oxide film exists through PECVD. FIG. 7 shows an X-ray diffraction analysis pattern of a c-Si layer onto which an electron beam was irradiated. As shown in FIG. 7, it could be known that crystallization peaks appeared on surfaces (111), (220), and (311) in case of the silicon onto which the electron beam was irradiated.

FIG. 8 shows a Raman spectrum of a c-Si layer as the same result of electron beam irradiation. Referring to FIG. 8, in case of the c-Si layer onto which the electron beam was irradiated, a peak was shown at a different location from the amorphous silicon, and a peak was shown at a similar location to the location of the crystalline silicon wafer, so that it could be known that silicon crystallization occurred through the electron beam irradiation.

### Analysis of Crystallization Surface According to Electron Beam Irradiation Versus Laser Irradiation

Amorphous silicon was deposited on two Si wafer substrates, and a crystallized c-Si layer was formed by irradiating an electron beam of 4 keV onto one substrate and irradiating a laser onto the other substrate.

In FIG. 9, (a) shows a scanning electron microscope image of a c-Si layer by the electron beam irradiation, and (b) shows a scanning electron microscope image of a crystallized c-Si layer by the laser irradiation. As shown in (a) and (b) of FIG. 9, the silicon crystallization by the electron beam irradiation has an advantage in that hill-lock does not exist on the grain boundary or the surface as compared with the silicon by the laser beam irradiation, and in this case, there is no grain boundary that provides a destruction path when pellicle thin film is free-standing, and thus the crystallization film by the electron beam irradiation may have an advantage of being not easily broken in comparison to the crystallization film by the laser beam irradiation.

### Test Example 2

### Graphene Layer Analysis

FIG. 10 shows a Raman spectrum of a graphene layer manufactured in Embodiment 1.

After deposition of an amorphous silicon layer with a thickness of 40 nm on the surface of a Si wafer through PECVD, a Ni metal thin film with a thickness of 10 nm was formed with a metal catalyst layer through sputtering. After a graphene precursor solution (polyimide/NMP solution, 101) was coated on the metal catalyst layer and dried for 20 minutes at 40° C., a graphene precursor cured coating film with a thickness of 25 nm was manufactured by performing heat curing for 20 minutes at 400° C. Here, Raman analysis was performed with respect to the graphene layer appeared on the surface through the electron beam irradiation.

Here, A, B, and C are peaks that appeared through the electron beam irradiation for 2 minutes with the electron beam energy of 4 keV, 3.5 keV, and 3 keV, respectively. Typical D peak and G peak that appeared when heat or energy was applied to the carbon layer represented a disorder peak and a graphite peak, respectively, and 2D was a typical peak that appeared only when the graphene was formed.

Referring to FIG. 10, together with 1350 cm¹:D peak and 1580 cm⁻¹:G peak, 2700 cm¹:2D peak was identified, and it could be known that the graphene thin film was formed by the electron beam energy and the Ni catalyst.

### EXPLANATION OF SYMBOLS

22: c-Si layer

42: graphene layer

50: binder layer

60: support frame

80: pellicle

90: reticle

92: mask substrate

93: EUV reflective mirror layer composed of 80 Si/Mo layers

94: mask pattern

### INDUSTRIAL APPLICABILITY

A pellicle for EUV according to the present disclosure is applicable to a lithography process of a semiconductor device.

1. A pellicle for extreme ultraviolet (EUV) lithography comprising:
a pellicle film that is penetrated by extreme ultraviolet (EUV) rays and a support frame that supports the pellicle film,
wherein the pellicle film has a multilayer thin film structure in which a crystallized silicon (c-Si) layer having no μm-sized grain boundary and a graphene thin film are heterojunctioned.

2. The pellicle of claim 1, wherein the c-Si is crystallized silicon, which has crystallization peaks on surfaces of (111), (220), and (311) in an X-ray diffraction (XRD) spectrum, and has a Raman shift value of 520 cm⁻¹ in a Raman spectrum.

3. The pellicle of claim 1, wherein the pellicle film is any one of c-Si/graphene, graphene/c-Si, c-Si/SiC/graphene, graphene/SiC/c-Si, c-Si/graphene/c-Si, graphene/c-Si/graphene, c-Si/SiC/graphene/SiC/c-Si, and graphene/SiC/c-Si/SiC/graphene structures.

4. The pellicle of claim 1, wherein the thickness of the pellicle film is 5 to 50 nm.

5. A method for manufacturing a pellicle for extreme ultraviolet (EUV) lithography including a pellicle film that is penetrated by extreme ultraviolet (EUV) rays and a support frame that supports the pellicle film, the method comprising the steps of:
(S1) forming a multilayer including a carbon layer, a metal catalyst layer, and an amorphous silicon layer on a substrate;
(S2) finally forming a multilayer thin film in which the c-Si layer and a graphene layer are heterojunctioned by simultaneously or sequentially performing steps of crystallizing the amorphous silicon layer with changing the amorphous silicon layer to a c-Si layer while a surface of the amorphous silicon layer is heated through irradiation of an electron beam thereto and the heat is diffused downward, diffusing carbon of the carbon layer by making the carbon of the carbon layer come up to an interface of the c-Si/metal catalyst layers through the metal catalyst layer, and then making the come-up carbon form a graphene at the interface;
(S3) performing diffusion bonding through a binder layer by making a support frame come in face-to-face contact with the binder layer on an outer periphery of the multiplayer after forming the binder layer on the outer periphery of the multilayer and forming the binder layer also on a surface of the face-to-face support frame; and
(S4) lifting off the multilayer thin film attached to the frame from the substrate.

6. The method of claim 5, further comprising the steps of:
after the step (S4),
(S5) forming any one or more of the amorphous silicon layer and the carbon layer on a bottom surface on an opposite side of the frame of the multilayer thin film attached to the frame; and
(S6) forming any one or more of the c-Si layer and the graphene layer on the bottom surface by irradiating the bottom surface with the electron beam.

7. The method of claim 5, further comprising etching the metal catalyst layer between the steps (S4) and (S5).

8. The method of claim 5, wherein the pellicle is any one of c-Si/graphene, graphene/c-Si, c-Si/SiC/graphene, and graphene/SiC/c-Si structures.

9. The method of claim 5, wherein the pellicle is any one of c-Si/graphene/c-Si, graphene/c-Si/graphene, c-Si/SiC/graphene/SiC/c-Si, and graphene/SiC/c-Si/SiC/graphene structures.

10. The method of claim 5, wherein the multilayer film is one multilayer film selected from the group consisting of an amorphous silicon layer/metal catalyst layer/carbon layer, an amorphous silicon layer/carbon layer/metal catalyst layer, a carbon layer/metal catalyst layer/amorphous silicon layer, a carbon layer/amorphous silicon layer/metal catalyst layer, a metal catalyst layer/carbon layer/amorphous silicon layer, and a metal catalyst layer/amorphous silicon layer/carbon layer.

11. The method of claim 5, wherein the metal catalyst layer is a single metal selected from the group consisting of Ni, Ti, Al, Zn, Co, Cu, Pt, Ag, and Au having a face centered cubic lattice (FCC) structure or an alloy thin film of two or more of the metals.

12. The method of claim 5, wherein the carbon layer is formed through any one method of graphene curing coating or chemical vapor deposition (CVD), plasma enhanced chemical vapor deposition (PECVD), sputtering, graphite ion beam deposition (IBD), physical vapor deposition, and vacuum deposition after coating and then curing of a graphene precursor solution.

13. The method of claim 12, wherein in the sputtering, graphite ion beam deposition (IBD), physical vapor deposition, and vacuum deposition, the carbon source is made through a process of singly using a graphite target or pellet or additionally adding a hydrocarbon gas thereto.

14. The method of claim 12, wherein the graphene precursor is one selected from the group consisting of polyimide, polyacrylonitrile, polymethyl methacrylate, polystyrene, rayon, lignin, pitch, borazine oligomer, or a mixture of one or more of them.

15. The method of claim 5, wherein one or a plurality of electron beam sources are used for the electron beam, the electronic beam sources are disposed in series or in parallel, and a uniform electron beam is processed in an entire pellicle area by using a circular or linear beam.

16. The method of claim 5, wherein the electron beam is applied with a voltage of 50 eV to 50 keV.

17. The method of claim 5, wherein the binder layer comprises a low-temperature melting metal; an eutectic alloy of which the melting temperature is lowered while any one of Zn, Ga, In, Sn, or Au is alloyed together with any one of Al, Si, Ti, Cr, Mn, Fe, Co, Ni, Cu, Zr, Nb, Mo, Te, Ru, Pd, Ag, or Pt; a general alloy; and a multilayer film selected from at least one of their oxide, nitride, carbide, and boride.

18. The method of claim 5, wherein the binder layer diffusion bonding is performed by applying a pressure of 0.1 Mpa to 1.0 Mpa at a temperature of 300° C. to 600° C.

19. The method of claim 5, wherein the lift-off is performed by separating the substrate and a multilayer thin film interface from each other through eruption of hydrogen, helium, nitrogen, and oxygen gases from a compound constituting the substrate, the multilayer thin film interface, or a separation layer by supplying heat onto the substrate after performing hydrophobic plasma processing on various kinds of metal, ceramic, or quartz plate substrates as a preprocessing process, plasma implantation processing on an Si wafer, deposition of a separation layer of any one of CuN, CuO, and Si:H on their substrates, and preprocessing through a combination of one or more of their methods.

20. A reticle for EUV lithography provided with the pellicle according to claim 1 to protect the photo mask from dust.
